(19) United States
(12) Patent Application Publication
(10) Pub. No.: US 2009/0246711 A1
(43) Pub. Date: Oct. 1, 2009

(54) METHOD FOR MANUFACTURING MAGNETIC RECORDING MEDIUM

(75) Inventor: Satomi KAJIWARA, Nagano (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/402,188

(22) Filed: Mar. 11, 2009

(30) Foreign Application Priority Data
Mar. 11, 2008 (JP) 2008-061258

(51) Int. Cl. G03F 7/20

(52) U.S. Cl. 430/320

(57) ABSTRACT

A method for manufacturing a patterned medium employing an imprinting method is provided, which can prevent the occurrence of resist pattern faults due to gas trapped between the imprinting mold surface and the resist layer, as well as resist pattern faults due to bubbles which can be formed in the resist film and at the resist surface. As preprocessing for an imprinting process, exposure processing is performed in which a substrate with a resist film formed on the surface thereof is exposed to an atmosphere at a temperature higher than the temperature at the time of imprinting and an environmental pressure lower than the environmental pressure at the time of imprinting.

### BACKGROUND

The invention relates to a method for manufacturing a magnetic recording medium.

In the prior art, there have been remarkable increases in the recording density of hard disks and other magnetic recording media, through reduction of the sizes of magnetic particles comprised by the recording layer, changes in materials, finer head shaping, and other improvements, and hereafter still higher recording densities are anticipated.

However, increases in recording densities through finer magnetic particles and other conventional methods of improvement have reached a limit; and discrete-type magnetic recording media, in which a continuous recording layer is divided into numerous recording elements, and groove portions between the divided recording elements are filled with nonmagnetic material, have been proposed as candidate magnetic recording media enabling still higher recording densities (see for example Japanese Patent Application Laid-open No. H9-97419).

An imprinting method is used as a method of pattern transfer during manufacture of these types of magnetic recording media. In the imprinting method, a mold (imprinting mold), in which is formed a pattern corresponding to a negative-positive inverted image of the pattern which is ultimately to be transferred, is pressed into resist, and in this state heat, ultraviolet rays, or similar are applied to harden the resist in order to transfer the pattern; methods employing thermal hardening are called thermal imprinting methods, and methods employing ultraviolet rays or similar for hardening are called optical imprinting methods. Thermal imprinting methods also include methods in which a thermoplastic resist is used, and the temperature is lowered to cause hardening of the resist.

First, thermal imprinting methods are explained. FIG. 1A through 1E are schematic cross-sectional diagrams showing an example of a pattern formation method employing thermal imprinting.

First, a silicon substrate 101 with a silicon oxide film 111 formed on the surface is prepared, and for example ordinary electron beam lithography is used to draw a pattern, followed by development and other patterning processing to form a resist pattern. The resist pattern is used as a mask and dry etching or similar is performed to etch the silicon oxide film 111, and the resist pattern is then stripped away to form an imprinting mold 100, with depressions 112 comprised by the silicon oxide film 111 formed on the silicon substrate 101 (see FIG. 1A).

Next, PMMA or another resist material is applied to a silicon substrate 102, to fabricate a resist layer formation substrate 110 on which a resist layer 121 is formed (see FIG. 1B).

Next, the resist layer formation substrate 110 on which the resist layer 121 has been formed is heated to approximately 120 to 200° C., to soften the resist layer 121. The imprinting mold 100 is then placed upon the resist layer formation substrate 110, the resist layer 121 of which has been softened, such that the depressions 112 of the imprinting mold 100 are opposed to the resist layer formation substrate 110, and pressure is applied at a pressure of approximately 3 to 20 MPa (see FIG. 1C).

Next, with the imprinting mold 100 pressed against the resist layer formation substrate 110, the temperature is lowered to approximately 100° C. or less, the resist layer 121 being pressed on the resist layer formation substrate 110 is hardened, and the imprinting mold 100 is released. By this mechanism, a resist pattern 121a and resist thin film regions 121b corresponding to the depressions 112 of the imprinting mold 100 are formed on the silicon substrate 102 (see FIG. 1D).

Next, the resist thin film region 121b is removed by an O₂ RIE method (reactive ion etching using oxygen gas), to form a resist pattern 121c on the silicon substrate 102 (see FIG. 1E). In this way, a resist pattern is formed on silicon substrate 102 using a thermal imprinting method. Because this method accompanies a heat cycle with heating and cooling processes, it is called thermal imprinting.

Next, an optical imprinting method is explained. FIGS. 2A through 2E are schematic cross-sectional diagrams showing an example of a pattern forming method using optical imprinting.

First, a pattern is drawn, for example using ordinary electron beam lithography, on an electron beam photosensitive layer formed on a transparent base, comprising quartz or another transparent material, and development and other patterning processes are performed to form a resist pattern. The resist pattern is used as a mask in dry etching or similar to etch the transparent substrate, the resist pattern is stripped away, and an imprinting mold 120 is fabricated, comprising the transparent base with depressions 121 formed in a transparent substrate (see FIG. 2A).

Next, a resist layer formation substrate 130 is fabricated, in which a liquid photohardening resin compound with low viscosity is applied to a glass substrate 102 to form a resist layer 122 (see FIG. 2B).

Next, the imprinting mold 120 is placed upon the resist layer formation substrate 130, such that the depressions 125 of the imprinting mold 120 are opposed to the resist layer formation substrate 130, pressure is applied at a low pressure of approximately 0.01 to 5 MPa, and the resist layer 122 is irradiated with UV light from the rear face of the imprinting mold 120 to harden the resist layer 122 (see FIG. 2C).

Next, the imprinting mold 120 is released. By this means, a resist pattern 122a and resist thin film regions 122b corresponding to the depressions 121 of the imprinting mold 120 are formed on the glass substrate 102 (see FIG. 2D).

Next, the resist thin film region 122b is removed by an O₂ RIE method (reactive ion etching using oxygen gas), to form a resist pattern 122c on the glass substrate 102 (see FIG. 2E).

In this way, an optical imprinting method is used to form a resist pattern on a glass substrate 102. By means of this method, resin hardening is performed through a photoreaction, so that there is no heat cycle (processes may be performed at room temperature), processing times can be greatly shortened, and there is no decline in positioning precision due to a heat cycle.

Further, because the photohardening resin compound is a liquid with low viscosity, pattern transfer can be performed without pressing the imprinting mold against the resist layer formation substrate with high pressure, as in the case of thermal imprinting.

However, in imprinting using the above thermal imprinting method or optical imprinting method, if the pressing of the imprinting mold against the resist layer formation substrate is performed in an atmospheric environment, air is trapped between the mold depressions and the resist, so that accurate transfer of the relief shape of the imprinting mold is not possible.

As measures to address this, a method in which, in an imprinting method, the process of stamping and pressing the imprinting mold against the resist layer formation substrate may be performed in vacuum, or a method in which the pressure with which the mold is pressed is made extremely large, to reduce the volume of the trapped air, may be employed.

Further, to address the problem of the occurrence of faults in the resist pattern due to air and similar trapped between the imprinting mold and the substrate when stamping and pressing of the imprinting mold is performed, reduced-pressure processing and heating processing at the time of imprinting has been proposed (see for example WO 2007-094213).

In this proposal, it is asserted that by setting mainly the pressing pressure during transfer at the time of imprinting, the depth of the depression pattern of the transfer object comprising the protrusion pattern used in transfer, the height of the protrusion pattern of the transfer material, and the pressure within the transfer space to respective values derived according to a certain relationship, transfer can be performed without problem, even if air is trapped and sealed within the depression pattern interior of the transfer mold.

For example, when as shown in FIG. 3A an imprinting mold 120 is used in stamping and pressing against a resist layer formation substrate 220 in which a resist layer 213 is formed on a glass substrate 203, although air trapped during pressing is compressed in the depressions of the imprinting mold 120 so that the volume of the air is reduced, the air remains in the depressions (see FIG. 3B).

At this time, the compressed air does not remain uniformly in the depressions of the imprinting mold 120, but instead remains as bubbles 215 in corner portions of the depressions of the mold 120, as shown in FIG. 3C.

Further, gases resulting from the vaporization of solvent and similar remaining in the resist film may, due to exposure to a vacuum during imprinting, move from within the film to the resist surface, to become bubbles 216 near the surface. Depending on the place, some bubbles may escape from the film to the outside, while others may remain in the film, so that a variety of bubbles are formed.

As a result, faults in corner portions, and a resist pattern 213a and resist thin film regions 213b having bubbles near the resist film interface, are formed in the glass substrate 203 after release of the imprinting mold 120, so that faults 217 occur in corner portions and near the surface of the resist pattern 213a.

The above-described method of performing the stamping and pressing process in vacuum requires substantial equipment to evacuate the device, resulting in cost increases, and in addition throughput is greatly reduced.

Further, in the above-described method of pressing with extremely high pressure, the imprinting mold itself may be deformed due to use of high pressure, so that positioning precision and the in-plane uniformity of thickness of the remaining film may be worsened; in addition, there is the possibility of breakage of the mold and substrate.

Conventional imprinting methods can be expected to be effective for removing gases trapped at the interface between mold and resist, but gases due to solvents remaining in the resist become bubbles at the resist film surface and in the film when the imprinting atmosphere is evacuated, and so there remains the problem that in subsequent processes such bubbles become pattern defects which do not perform the masking function.

In WO 2007-094213, it is stated that reduced-pressure processing and heating processing at the time of imprinting are preferable; but such reduced-pressure processing and heating processing is intended solely to remove gas trapped at the interface of the mold and resist, and moreover is limited to conditions in which the main purpose is molding of the resin or similar for pattern transfer. That is, parameters cannot be set to conditions resulting in poor moldability of the resin. Further, removal of bubbles due to solvent and other gases remaining in the resist is difficult.

Hence when the relation “imprinting conditions=conditions under which occurrence of bubbles can be completely prevented” does not obtain, bubbles remain in the molded resin, and similarly to the technology of the prior art, these become faults which do not function as a mask material, so that the above-described problem is not resolved.

### SUMMARY OF THE INVENTION

The invention was devised in light of the above problems, and provides a method for manufacturing a patterned medium, employing an imprinting method in which, in the stamping and pressing processes of the imprinting method, the occurrence of resist pattern faults due to gas trapped between the imprinting mold surface and the resist layer, and the occurrence of resist pattern faults due to bubbles which can be formed in the resist film and at the resist surface, can be prevented.

That is, a method for manufacturing a magnetic recording medium is a method for manufacturing a magnetic recording medium employing an imprinting method for pattern formation, characterized in that, as preprocessing for an imprinting process, exposure processing is performed in which a substrate with a resist film formed on the surface thereof is exposed to an atmosphere at a temperature higher than the temperature at the time of imprinting and an environmental pressure lower than the environmental pressure at the time of imprinting.

By means of this invention, pattern defects arising due to bubbles in the resist film surface and in the film at the time of imprinting, caused by solvent and other gases remaining in the resist, can be efficiently prevented.

That is, in order to resolve the above problem, the substrate with resist formed is exposed, prior to imprinting, to an atmosphere at a higher temperature than the heating temperature during imprinting and to a low environmental pressure, so that even after subsequently being exposed to the heating temperature and environmental pressure during imprinting, having once been exposed to a higher temperature and lower environmental pressure, gases which might have been emitted from within the resist film have already been emitted, so that during imprinting there is no further emission, pattern transfer free of pattern faults can be performed, and a high-quality magnetic recording medium can be manufactured.

### BRIEF DESCRIPTION OF THE DRAWINGS

The invention will be described with reference to certain preferred embodiments thereof and the accompanying drawings, wherein:

FIG. 1 explains processes to form a resist pattern by a thermal imprinting method of the prior art;

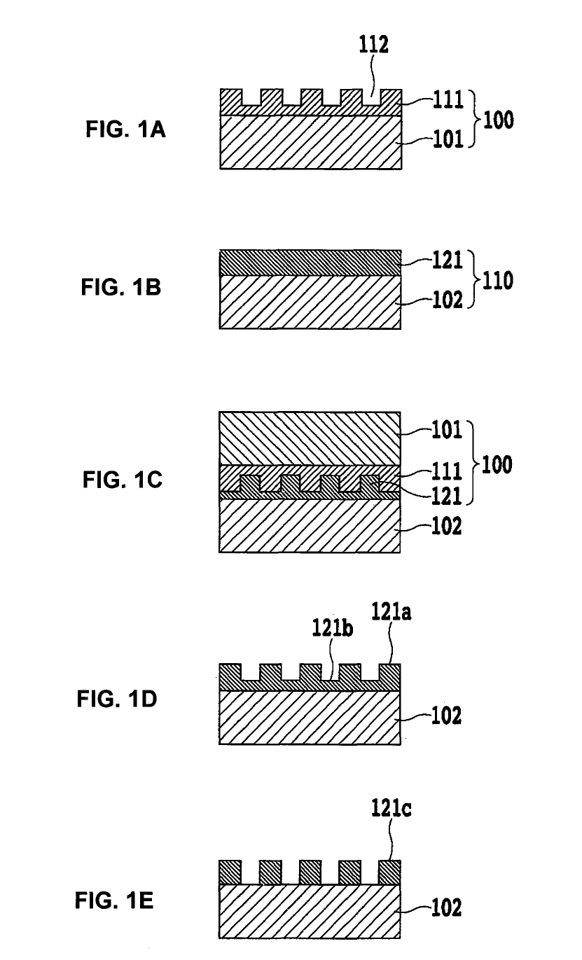

FIG. 2 explains processes to form a resist pattern by an optical imprinting method of the prior art;

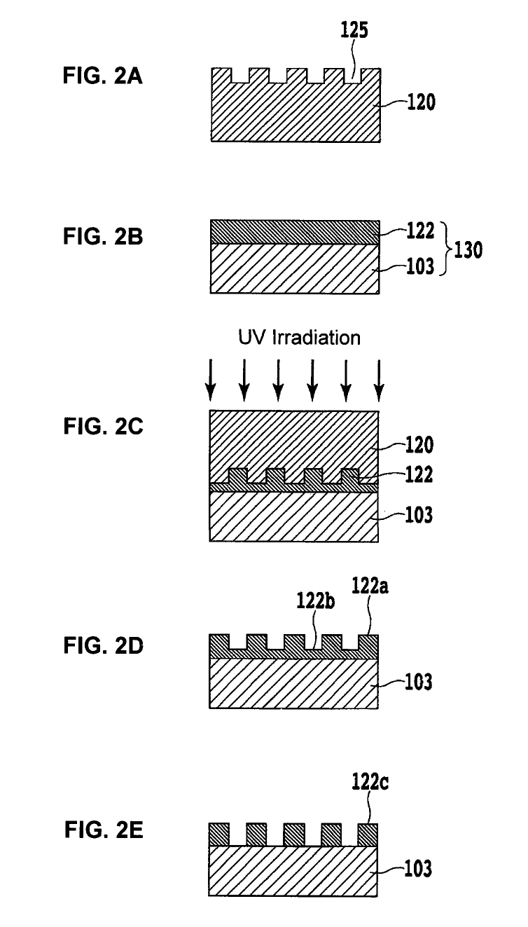

FIGS. 3A through 3E explain fault generation when forming a resist pattern using an imprinting method of the prior art;

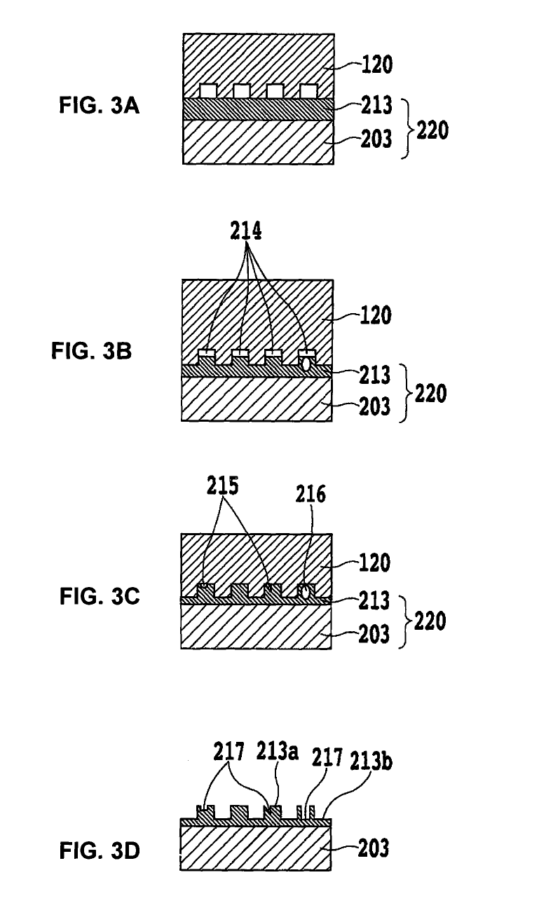

FIGS. 4A through 4E explain bubble removal by processing prior to imprinting in this invention;

FIGS. 5A through 5F explain manufacturing processes for a patterned magnetic recording medium in which a resist pattern is formed by a thermal imprinting method using exposure processing of this invention;

FIGS. 6A through 6E explain manufacturing processes for a patterned magnetic recording medium in which a resist pattern is formed by a thermal imprinting method not using exposure processing of this invention;

FIGS. 7A through 7F explain manufacturing processes for a patterned magnetic recording medium in which a resist pattern is formed by an optical imprinting method using exposure processing of this invention; and,

FIGS. 8A through 8E explain manufacturing processes for a patterned magnetic recording medium in which a resist pattern is formed by an optical imprinting method not using exposure processing of this invention.

### DESCRIPTION OF THE PREFERRED EMBODIMENTS

As an imprinting method employed in a method for manufacturing a magnetic recording medium of this invention, either a thermal imprinting method, or an optical imprinting method can be used.

In the case of a thermal imprinting method, polymethyl methacrylate (PMMA) or another thermoplastic resin, or epoxy or another thermohardening resin can be used as the resist film; in the case of an optical imprinting method, a UV-hardening resin can be used.

As the imprinting mold used in imprinting, any mold normally used in thermal imprinting or optical imprinting can be used. However, materials such as polydimethyl siloxane (PDMS), polyimides, polyamides, polycarbonate, epoxy resin, and other polymer materials; copper, nickel, tantalum, titanium, silicon, and other metals and alloys; quartz and other glass materials; silicon oxide (SiO₂), silicon carbide (SiC), carbon, sapphire, and similar, are used as appropriate according to the characteristics required for thermal imprinting or optical imprinting.

As the substrate on the surface of which the resist film is to be formed (the substrate of the magnetic recording medium), any substrate normally used in a magnetic recording medium can be employed. However, a substrate on which a magnetic recording layer has been formed is used. When the substrate is for a perpendicular magnetic recording medium, this magnetic recording layer adopts a layered structure comprising a soft magnetic underlayer, intermediate layer, and ferromagnetic recording layer. As the magnetic recording layer, or as the ferromagnetic recording layer of a perpendicular magnetic recording medium, a CoPt system alloy, or a CoPt alloy to which Cr, Ni, Ta, or similar has been added, can be used.

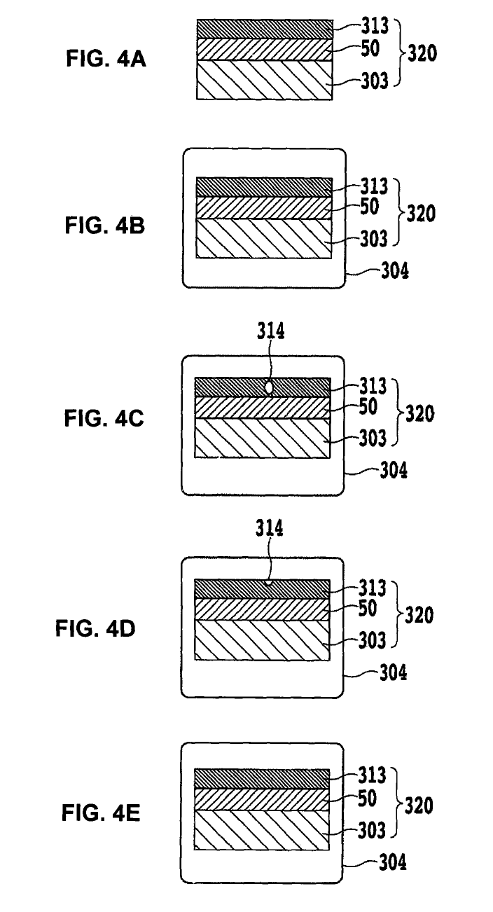

Next, exposure processing in a method for manufacturing a magnetic recording medium of this invention is explained, referring to FIG. 4. A resist layer formation substrate 320 is fabricated, with resist for imprinting applied onto a glass substrate 303 to form a resist layer 313 (see FIG. 4A).

Next, the resist layer formation substrate 320 with the resist layer 313 formed is put into an elevated temperature state between the glass transition temperature of the resist and the glass transition temperature +100° C. (between 50° C. and 350° C.), for example, and left for several minutes to several tens of minutes in a chamber 304 under a pressure of 500 Pa to 1100 Pa (see FIG. 4B).

The temperature and pressure may be adjusted to the optimum temperature and pressure within the above ranges, according to the type of imprinting resist, the molding temperature during imprinting, and the molding pressure (vacuum).

In this invention, in order to completely remove gases from within the resist film, to ensure a state in which gases do not remain in a bubble state within the resist film, a pressure is applied which is lower than the pressure during imprinting. And, the resist film is raised to approximately the glass transition temperature during degasification. By means of these conditions, degasification can be performed more smoothly (see FIGS. 4C and 4D).

After degasification, the resist film is left in the above environmental conditions so that, through its own fluidity, the vestiges of the degasification cleanly vanish (see FIG. 4E). The time duration and the environmental temperature should be set appropriately according to the fluidity of the resist at that temperature; however, it is preferable that the processing time for exposure processing, including the time left in the environmental conditions, be the same as or longer than the time required for the imprinting process.

Using a resist layer formation substrate which has been exposure-processed in this way, stamping is performed using the thermal imprinting method or optical imprinting method, and after pressing to transfer the pattern of the imprinting mold to the resist layer formation substrate in negative-positive transfer to form a relief pattern, a well-known method is used to manufacture the magnetic recording medium.

The temperature during stamping is lower than the temperature during exposure processing; for example, in the temperature range of approximately 45° C. to 300° C., the pressure during stamping is higher than the environmental pressure during exposure processing, that is, stamping is performed in a chamber at for example 600 to 1200 Pa. The pressing force of stamping is approximately 5 to 20 MPa. Next, with the pressure force applied, the resist is hardened, and moreover the temperature is lowered to a temperature at which handling is easy, such as approximately 40° C. to 70° C., and the imprinting mold is released. By this means, a resist pattern corresponding to the depressions in the imprinting mold, and regions in which the resist is a thin film (called resist thin film regions), are formed on the substrate.

Next, an etching method such as for example reactive ion etching is used to etch the resist thin film regions to expose the substrate surface in those regions, forming a resist pattern on the substrate. The gas used in reactive ion etching is a gas which more easily etches the resist than the substrate, such as for example oxygen gas.

Portions without resist of the substrate on which the resist pattern has been formed are etched by reactive ion etching using a gas which more easily etches the substrate, and particular the magnetic recording layer, than the resist; for example, a fluorocarbon gas is used, and the relief pattern formed in the imprinting mold is formed in the substrate. Then, the remaining resist is removed by for example oxygen plasma, so that a substrate can be obtained on which is a magnetic recording layer having the prescribed pattern. Thereafter, well-known technology normally employed in magnetic recording medium manufacture can be used to manufacture a magnetic recording medium using this substrate.

### Embodiment 1

### Thermal Imprinting Method

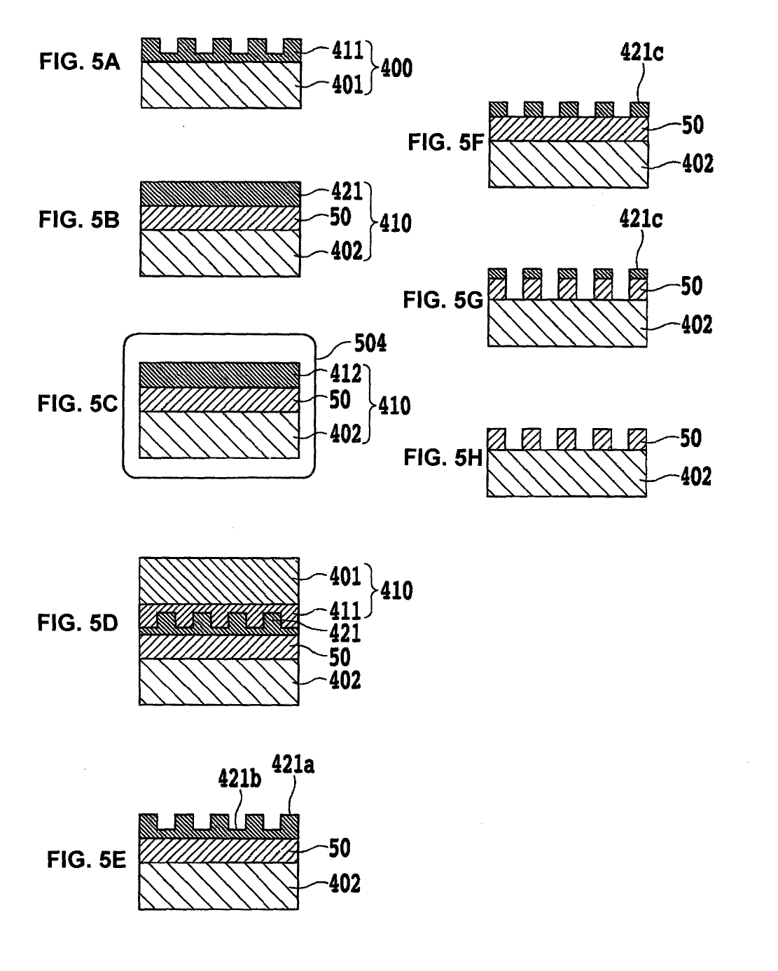

This embodiment is an embodiment of a magnetic recording medium manufacturing method employing a thermal imprinting method, and is described referring to FIG. 5. FIGS. 5A through 5H are schematic cross-sectional diagrams showing an example of a pattern formation method using thermal imprinting and manufacture of a patterned magnetic recording medium.

First, silicon substrate 401 was prepared, with a silicon oxide film 411 formed on the surface; a pattern was drawn in an electron-beam photosensitive layer formed on the silicon oxide film 411 on the silicon substrate 401 using ordinary electron beam lithography, development and other patterning processing was performed, the resist pattern was formed, and the resist pattern was used as a mask to etch the silicon oxide film 411 by dry etching or other means. The resist pattern was stripped away, and in this way an imprinting mold 400 was fabricated, with depressions 412 comprised by the silicon oxide film 411 formed on the silicon substrate 401 (see FIG. 5A).

Next, a thermoplastic resist (mr-I8010E, manufactured by MicroResist Technology, glass transition temperature 115° C.) was spin-coated onto a magnetic recording layer 50 provided on a medium substrate 402 at 3000 rpm to a thickness of 100 nm, to fabricate a resist layer formation substrate 410 on which a resist layer 421 was formed (see FIG. 5B).

Next, the resist layer formation substrate 410 on which the resist layer 421 was formed was placed in an exposure chamber 504, the chamber interior was heated to 210° C. in a vacuum atmosphere of 1000 Pa, and exposure processing was performed for 300 seconds to soften the resist layer, completely degasifying the bubbles which had remained in the resist layer (see FIG. 5C).

Next, the resist layer formation substrate 410 on which the resist layer 421 was formed was heated to 200° C., the resist layer 421 was softened, and then the imprinting mold 410 was placed on the resist layer formation substrate 410 with softened resist layer 421, with the depressions 412 in the imprinting mold 400 in opposition, and pressure is applied at a pressure of 10 MPa (see FIG. 5D).

Next, with the imprinting mold 400 pressed against the resist layer formation substrate 410, the temperature was lowered to 60° C., the stamped resist layer 421 on the resist layer formation substrate 410 was hardened, and the imprinting mold 400 was released.

By this mechanism, a resist pattern 421a and resist thin film regions 421b corresponding to the depressions 412 of the imprinting mold 400 were formed on the medium substrate 402 (see FIG. 5E).

Next, the resist thin film regions 421b were removed by O₂ RIE (reactive ion etching using oxygen gas), and a resist pattern 421c was formed on the medium substrate (see FIG. 5F).

Thereafter, magnetic recording layer shaping was performed. That is, using the resist pattern 421c of the resist layer formation substrate 410 as a mask, RIE (reactive ion etching) was performed using a fluorocarbon (CF₄, CHF₃, C₂F₈) as the reactive gas, to shape the magnetic recording layer 50 by anisotropic dry etching (see FIG. 5G).

At this time, as explained above, by performing exposure processing in the chamber for exposure prior to imprinting, a resist pattern 421c can be formed without faults, so that when this resist pattern is used as a mask in shaping the magnetic recording layer, the magnetic recording medium can be shaped without faults arising from the resist pattern mask. Thereafter, the resist pattern 421c used as a mask was removed using oxygen plasma (see FIG. 5H).

### Comparative Example 1

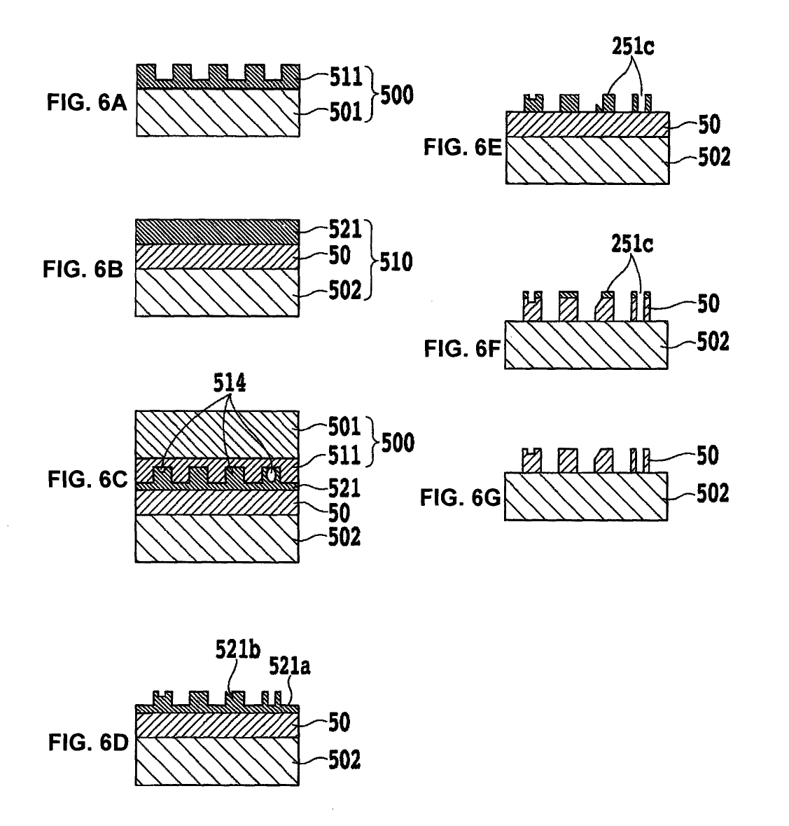

This comparative example is an example of the use of an ordinary thermal imprinting method, without performing exposure processing, and is explained referring to FIGS. 6A through 6G, which are schematic cross-sectional diagrams showing an example of pattern formation using a thermal imprinting method and a method for manufacturing a patterned magnetic recording medium.

First, a silicon substrate 501 on the surface of which is formed a silicon oxide film 511 was prepared, and a pattern was drawn on an electron-beam photosensitive layer formed on the silicon oxide film 511 on the silicon substrate 501 by, for example, ordinary electron beam lithography; development and other patterning processing was performed, a resist pattern was formed, the resist pattern was used as a mask to etch the silicon oxide film 511 by dry etching or similar, the resist pattern was stripped away, and in this way an imprinting mold 500 was fabricated, with depressions 512 comprised by the silicon oxide film 511 formed on the silicon substrate 501 (see FIG. 6A).

Next, a thermoplastic resist (mr-I8010E, manufactured by MicroResist Technology, glass transition temperature 115° C.) was spin-coated onto a magnetic recording layer 50 provided on a medium substrate 502 at 3000 rpm to a thickness of 100 nm, to fabricate a resist layer formation substrate 510 on which a resist layer 521 was formed (see FIG. 6B).

Next, the resist layer formation substrate 510, on which the resist layer 521 was formed, was heated to 210° C., at which imprinting is to be performed, the resist layer 521 was softened, and then the imprinting mold 510 was placed over the resist layer formation substrate 510 on which the resist layer 521 had been softened, with the depressions 512 of the imprinting mold 500 opposing, and 10 MPa of pressure was applied.

At this time, in order to perform imprinting, the resist layer 521 was heated to 210° C., which was optimized only for pattern moldability, so that while there was fluidity, the temperature was not adequate for the removal of bubbles 514 comprised within the resist layer 521, and because the environmental pressure was atmospheric pressure, bubbles within the resist layer 521 were not removed during imprinting. As a result, bubbles 514 remained in the molded resist pattern (see FIG. 6C).

Next, with the imprinting mold 500 pressed against the resist layer formation substrate 510, the temperature was lowered to 60° C., the stamped resist layer 521 on the resist layer formation substrate 510 was hardened, and the imprinting mold 500 was released.

By this means, a resist pattern 521a and resist thin film regions 521b corresponding to the depressions 512 of the imprinting mold 500 were formed on the magnetic recording layer 50 provided on the medium substrate 502 (see FIG. 6D).

Next, the resist thin film regions 521b were removed by O₂ RIE (reactive ion etching using oxygen gas), and the resist pattern 521c was formed on the medium substrate (see FIG. 6E). The resist pattern formed in this way had pattern faults, arising from bubbles which could not be removed at the time of imprinting.

Then, shaping of the magnetic recording layer was performed. That is, using the resist pattern 521c of the resist layer formation substrate 510 as a mask, RIE using a fluorocarbon system (CF₄, CHF₃, C₂F₈) reactive gas was employed to shape the magnetic recording layer 50 by anisotropic dry etching (see FIG. 6F).

At this time, as explained above, because pattern faults had occurred in the resist pattern 521c during imprinting, the magnetic recording medium after shaping had faults caused by the resist pattern mask. Thereafter, the resist pattern 521c which had been used as a mask was removed using oxygen plasma (see FIG. 6G).

### Embodiment 2

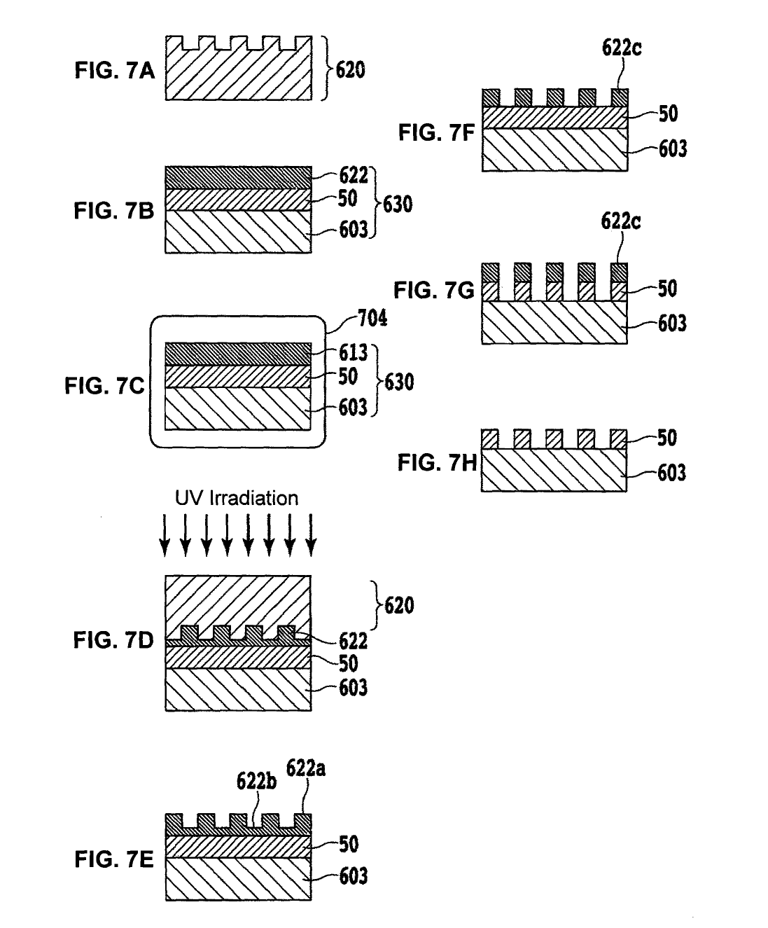

Next, an embodiment of this invention is explained for a case in which optical imprinting is used, referring to FIG. 7. FIGS. 7A through 7H are schematic cross-sectional diagrams showing an example of pattern formation by optical imprinting and a method for manufacturing a patterned magnetic recording medium.

First, a pattern was drawn on an electron-beam photosensitive layer formed on a transparent base comprising translucent material such as quartz using ordinary electron beam lithography, development and other patterning processing was performed to form a resist pattern, the resist pattern was used as a mask to etch the transparent base by dry etching or similar, the resist pattern was stripped away, and an imprinting mold 620 comprising a transparent base with depressions 625 formed on the transparent substrate was fabricated (see FIG. 7A).

Next, a UV-hardening resin (PAK-01, manufactured by Toyo Gosei) was applied, as a resist, onto a magnetic recording layer 50 provided on a medium substrate 603 by spin-coating at 2500 rpm to a thickness of 100 nm, to fabricate a resist layer formation substrate 630 on which was formed a resist layer 613 (see FIG. 7B).

Next, the resist layer formation substrate 630 with resist layer 613 formed was placed in a chamber for exposure 704, heating to approximately 100° C. was performed in a vacuum of 1000 Pa, exposure processing was performed for 30 seconds to soften the resist layer, and bubbles remaining in the resist layer were completely removed (see FIG. 7C).

Next, the transparent-base mold 620 was placed on the resist layer formation substrate 630 on which the resist layer 613 was formed, with the depressions 625 of the imprinting mold 620 opposing the resist layer formation substrate 630, a pressure of 0.1 MPa was applied, and UV light of wavelength 400 nm or less was irradiated for 10 seconds from the rear face of the imprinting mold 620, to harden the resist layer 613 (see FIG. 7D).

Next, the imprinting mold 620 was released. By this means, a resist pattern 622a and resist thin film regions 622b corresponding to the depressions 625 of the imprinting mold 620 were formed on the medium substrate 603 (see FIG. 7E).

Next, the resist thin film regions 622b were removed by O₂ RIE (reactive ion etching using oxygen gas), and a resist pattern 622c was formed on the medium substrate 603 (see FIG. 7F).

Then, shaping of the magnetic recording layer was performed. That is, the resist pattern 622c of the resist layer formation substrate 630 was used as a mask in RIE using a fluorocarbon system (CF₄, CHF₃, C₂F₈) reactive gas, and the magnetic recording layer 50 was shaped by anisotropic dry etching (see FIG. 7G).

At this time, as explained above, by performing exposure processing in a chamber for exposure prior to imprinting, the resist pattern 622c could be formed without faults, so that when using this resist pattern as a mask in shaping the magnetic recording layer, it was possible to shape the magnetic recording medium without faults arising from the resist pattern mask. Thereafter, the resist pattern 622c which had been used as a mask was removed using oxygen plasma (see FIG. 7H).

### Comparative Example 2

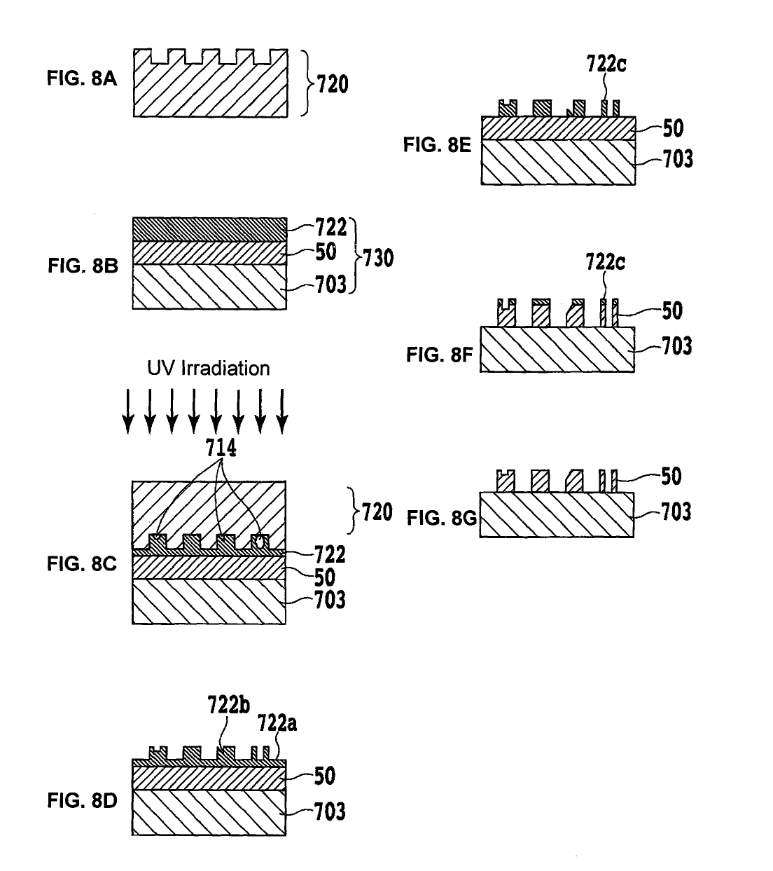

This comparative example is an example in which ordinary optical imprinting was used, without performing exposure processing, and is explained referring to FIGS. 8A through 8G, which are schematic cross-sectional diagrams showing an example of pattern formation using optical imprinting and a method for manufacturing a patterned magnetic recording medium.

First, a pattern was drawn on an electron-beam photosensitive layer formed on a transparent base comprising translucent material such as quartz, using for example ordinary electron beam lithography, development and other patterning processing was performed, a resist pattern was formed, the resist pattern was used as a mask to etch the transparent base by dry etching or similar, the resist pattern was stripped away, and an imprinting mold 720 comprising a transparent base with depressions 725 formed in the transparent substrate was fabricated (see FIG. 8A).

Next, a UV-hardening resin (PAK-01, manufactured by Toyo Gosei) was applied, as a resist, onto a magnetic recording layer 50 provided on a medium substrate 703 by spin-coating at 2500 rpm to a thickness of 100 nm, to fabricate a resist layer formation substrate 730 on which was formed a resist layer 722 (see FIG. 8B).

Next, the transparent-base mold 720 was placed on the resist layer formation substrate 730 on which the resist layer 722 was formed, with the depressions 725 of the imprinting mold 720 opposing the resist layer formation substrate 730, a pressure of 0.1 MPa was applied, and UV light of wavelength 400 nm or less was irradiated for 10 seconds from the rear face of the imprinting mold 720, to harden the resist layer 722.

At this time, in order to perform imprinting, the resist layer 722 was heated to 210° C., which was optimized only for pattern moldability, so that while there was fluidity, the temperature was not adequate for the removal of bubbles 714 comprised within the resist layer 722, and because the environmental pressure was atmospheric pressure, bubbles within the resist layer 722 could not be removed during imprinting, so that bubbles 714 remained in the molded resist pattern (see FIG. 8C).

Next, the imprinting mold 720 was released. By this means, a resist pattern 722a and resist thin film regions 722b corresponding to depressions 725 in the imprinting mold 720 were formed on the magnetic recording layer 50 provided on the medium substrate 703 (see FIG. 8D).

Next, the resist thin film regions 722b were removed by O₂ RIE (reactive ion etching using oxygen gas), and the resist pattern 722c was formed on the medium substrate 703 (see FIG. 8E). The resist pattern thus formed had pattern faults caused by bubbles which could not be removed at the time of imprinting.

Then, magnetic recording layer shaping was performed. That is, using the resist pattern 521c of the resist layer formation substrate 510 as a mask, RIE using a fluorocarbon system (CF₄, CHF₃, C₂F₈) reactive gas was employed to shape the magnetic recording layer 50 by anisotropic dry etching (see FIG. 8F).

At this time, as explained above, because pattern faults had occurred in the resist pattern 521c during imprinting, the magnetic recording medium after shaping had faults caused by the resist pattern mask. Thereafter, the resist pattern 521c which had been used as a mask was removed using oxygen plasma (see FIG. 8G).

According to this invention, by exposing a substrate on which resist is formed, prior to imprinting, to an atmosphere with higher temperature than the heating temperature during imprinting and with low environmental pressure, pattern transfer free of faults can be performed, and a high-quality magnetic recording medium can be manufactured.

The invention has been described with reference to certain preferred embodiments thereof. It will be understood that modifications and variations are possible within the scope of the appended claims.

This application is based on, and claims priority to, Japanese Patent Application No: 2008-061258, filed on Mar. 11, 2008. The disclosure of the priority application, in its entirety, including the drawings, claims, and the specification thereof, is incorporated herein by reference.

What is claimed is:

1. A method for manufacturing a magnetic recording medium, employing an imprinting method for pattern formation, wherein, as preprocessing for an imprinting process, exposure processing is performed in which a substrate with a resist film formed on the surface thereof is exposed to an atmosphere at a temperature higher than the temperature at the time of imprinting and an environmental pressure lower than the environmental pressure at the time of imprinting.

2. The method for manufacturing a magnetic recording medium according to claim 1, wherein the resist film is a resist film for thermal imprinting, and the temperature during exposure processing is from a glass transition temperature of the resist film to the glass transition temperature +100° C.

3. The method for manufacturing a magnetic recording medium according to claim 1, wherein the resist film is a resist film for optical imprinting, and the temperature during exposure processing is a temperature enabling the resist film to be put into a softened state.

4. The method for manufacturing a magnetic recording medium according to claim 1, wherein the processing time of the exposure processing is the same as or longer than the time required for the imprinting process.

5. The method for manufacturing a magnetic recording medium according to claim 2, wherein the processing time of the exposure processing is the same as or longer than the time required for the imprinting process.

6. The method for manufacturing a magnetic recording medium according to claim 3, wherein the processing time of the exposure processing is the same as or longer than the time required for the imprinting process.
